(19) United States
(12) Patent Application Publication
(10) Pub. No.: US 2026/0319989 A1
(43) Pub. Date: Oct. 15, 2026

(54) ADDRESS ASSIGNMENT METHOD, SENSOR NETWORK SYSTEM, DISPLACEMENT DETECTION DEVICE, NON-TRANSITORY COMPUTER-READABLE MEDIUM, AND INTEGRATED CIRCUIT DEVICE

(71) Applicant: Asahi Kasei Microdevices Corporation, Tokyo (JP)

(72) Inventors: Satoshi Kido, Tokyo (JP); Yoshihiko Koizumi, Tokyo (JP)

(73) Assignee: Asahi Kasei Microdevices Corporation, Tokyo (JP)

(21) Appl. No.: 19/461,645

(22) Filed: Jan. 27, 2026

(30) Foreign Application Priority Data
Mar. 26, 2025 (JP) 2025-052502

(51) Int. Cl. G06F 13/40; G01R 33/02

(52) U.S. Cl. CPC G06F 13/404; G01R 33/02; G06F 2213/0052

(57) ABSTRACT

An address assignment method includes: a stage in which a magnetic measurement section of each of multiple integrated circuit devices measures a magnetic field; and a stage in which an address of each of the multiple integrated circuit devices is generated based on the magnetic field. A sensor network system includes: multiple integrated circuit devices each having a magnetic measurement section that measures a magnetic field; and a control device communicably connected to the multiple integrated circuit devices, in which an address of each of the multiple integrated circuit devices is generated based on the magnetic field measured by the magnetic measurement section.

### CROSS-REFERENCE TO RELATED APPLICATION

This application claims the priority benefit of Japan application serial no. 2025-052502, filed on Mar. 26, 2025. The entirety of the above-mentioned patent application is hereby incorporated by reference herein and made a part of this specification.

### BACKGROUND

### Technical Field

The disclosure relates to an address assignment method, a sensor network system, a program, and an integrated circuit device.

### Related Art

U.S. Patent No. 8,775,714 describes “a system and method for a bus interface.”

### SUMMARY

In a first aspect, an address assignment method is provided including: a stage in which a magnetic measurement section of each of multiple integrated circuit devices measures a magnetic field; and a stage in which an address of each of the multiple integrated circuit devices is generated based on the magnetic field.

In the above address assignment method, the stage in which the address is generated may include a stage in which an address generation section of each of the multiple integrated circuit devices generates the address based on the magnetic field.

Any of the above address assignment methods may include a stage in which an interface processing section of each of the multiple integrated circuit devices transmits the address generated by the address generation section to a control device communicably connected to the multiple integrated circuit devices.

Any of the above address assignment methods may include: a stage in which the control device accesses each of the multiple integrated circuit devices using the address received from the interface processing section as a provisional address; and a stage in which the control device regenerates the address of at least one of the multiple integrated circuit devices.

In any of the above address assignment methods, the stage in which the address is generated may include a stage in which the address corresponding to a position of each of the multiple integrated circuit devices is generated based on the magnetic field.

In any of the above address assignment methods, the stage in which the address is generated may include a stage in which an address of each of the multiple integrated circuit devices is generated based on at least one of magnitude and direction of the magnetic field.

In any of the above address assignment methods, the stage in which the magnetic field is measured may include a stage in which the magnetic measurement section measures a magnetic field generated by a magnetic field generation section whose position relative to the multiple integrated circuit devices is variable.

In any of the above address assignment methods, the stage in which the magnetic field is measured may include a stage in which the magnetic measurement section measures a magnetic field generated by a current flowing through a wiring part that connects a first terminal of each of the multiple integrated circuit devices in series.

In any of the above address assignment methods, the stage in which the magnetic measurement section measures the magnetic field generated by the current flowing through the wiring part may include a stage in which each of the multiple integrated circuit devices draws the current flowing through the wiring part from the first terminal into inside.

In a second aspect, a sensor network system is provided including: multiple integrated circuit devices, each including a magnetic measurement section that measures a magnetic field; and a control device, communicably connected to the multiple integrated circuit devices, in which an address of each of the multiple integrated circuit devices is generated based on the magnetic field measured by the magnetic measurement section.

In the above sensor network system, the control device may be communicably connected to the multiple integrated circuit devices via a serial interface.

In a third aspect, a displacement detection device is provided including any of the above sensor network systems.

In a fourth aspect, a non-transitory computer-readable medium is provided, storing a program that, when executed by a computer, causes the computer to: control a magnetic measurement section of each of multiple integrated circuit devices to measure a magnetic field; and generate an address of each of the multiple integrated circuit devices based on the magnetic field.

In a fifth aspect, an integrated circuit device is provided including: a magnetic measurement section, measuring a magnetic field; an address generation section, generating an address based on the magnetic field; and an interface processing section, outputting the address.

The above summary does not enumerate all features of the disclosure. Sub-combinations of these feature groups may also constitute inventions.

### BRIEF DESCRIPTION OF THE DRAWINGS

FIG. 1 shows an overview of a configuration of a sensor network system 100.

FIG. 2 shows an example of an address assignment method.

FIG. 3A shows an example of a sensor network system 500 according to a comparative example.

FIG. 3B shows an example of the sensor network system 500 according to a comparative example.

FIG. 3C shows an example of the sensor network system 500 according to a comparative example.

FIG. 4 shows a modification of an address assignment method.

FIG. 5 shows an example of the sensor network system 100.

FIG. 6A shows a partial perspective view of a modification of the sensor network system 100.

FIG. 6B shows a bottom view of a modification of the sensor network system 100.

FIG. 7 shows an example of a computer 1000 in which multiple aspects of the disclosure may be embodied in whole or in part.

### DESCRIPTION OF THE EMBODIMENTS

The following embodiments do not limit the invention according to the claims. Not all combinations of features described in the embodiments are necessarily essential to the solution of the invention.

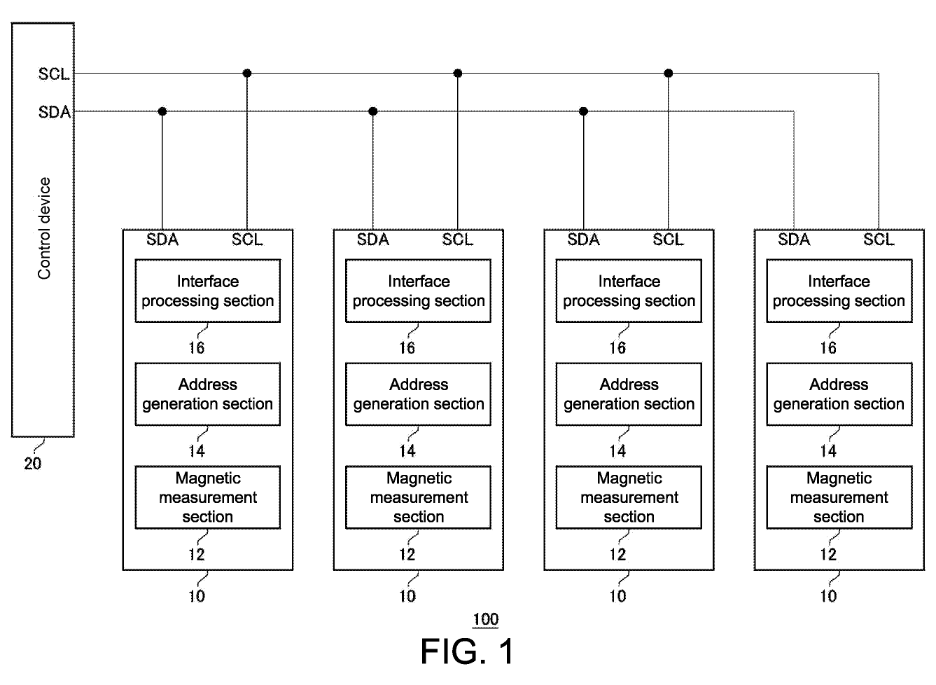

FIG. 1 shows an overview of a configuration of a sensor network system 100. The sensor network system 100 includes multiple integrated circuit devices 10 and a control device 20. While the sensor network system 100 of the present example includes four integrated circuit devices 10, the number of the multiple integrated circuit devices 10 is not limited thereto.

The sensor network system 100 may be used in a displacement detection device including the sensor network system 100. As one example, the sensor network system 100 is a sensor network system that detects a position and/or speed of a piston in a cylinder having the piston built therein. As another example, the sensor network system 100 may be a sensor network system that measures pressure fluctuation and/or flow rate of fluid flowing in a pipe, or a sensor network system that measures load at each position of a measurement target, or a sensor network system that detects pressing and releasing of multiple buttons provided on a gaming controller, or a sensor network system that detects a control state of a joint of a robot arm.

The multiple integrated circuit devices 10 are integrated circuit devices that function as sensors in the sensor network system 100. Each of the multiple integrated circuit devices 10 may be an integrated circuit device having a unique address. For example, the unique address is an address predetermined according to the type and/or manufacturer of the product. The multiple integrated circuit devices 10 may be the same product as each other. In this case, the multiple integrated circuit devices 10 have the same unique address as each other.

Each of the multiple integrated circuit devices 10 includes a magnetic measurement section 12, an address generation section 14, and an interface processing section 16.

The magnetic measurement section 12 measures a magnetic field. The magnetic measurement section 12 may be a magnetic sensor such as a Hall effect sensor or magnetoresistive sensor. However, the type of the magnetic measurement section 12 is not limited thereto. The magnetic measurement section 12 may provide information relating to the measured magnetic field to the address generation section 14.

The magnetic field measured by the magnetic measurement section 12 may be a magnetic field having a position-dependent distribution. For example, the magnetic field measured by the magnetic measurement section 12 is a magnetic field in which at least one of magnitude and direction differs according to the positions of the multiple integrated circuit devices 10. Details of the magnetic field measured by the magnetic measurement section 12 will be described later.

The address generation section 14 generates an address based on the magnetic field measured by the magnetic measurement section 12. The address generation section 14 may generate an address based on the magnetic field measured by the magnetic measurement section 12 in accordance with a predetermined magnetic field-address conversion algorithm. The address generated by the address generation section 14 may be the same as or different from the unique address of the integrated circuit device 10. For example, the address generation section 14 may generate an address by rewriting the last two digits of the unique address based on the magnetic field measured by the magnetic measurement section 12. In this case, if the last two digits rewritten based on the magnetic field are the same as the last two digits of the unique address, the address generated by the address generation section 14 is the same as the unique address; if the last two digits rewritten based on the magnetic field are different from the last two digits of the unique address, the address generated by the address generation section 14 is different from the unique address.

The method for generating an address by the address generation section 14 is not limited to the above. For example, in the case where the number of the multiple integrated circuit devices 10 is 5 or more and 8 or less, the address generation section 14 may generate an address by rewriting the last 3 digits of the unique address; similarly, in the case where the number of the multiple integrated circuit devices 10 is 9 or more, the number of digits to be rewritten may be changed. The address generation section 14 may generate an address by a method other than rewriting the unique address.

The address generation section 14 may generate an address based on at least one of magnitude and direction of the magnetic field measured by the magnetic measurement section 12. As described above, for example, the magnetic field measured by the magnetic measurement section 12 is a magnetic field in which at least one of magnitude and direction differs according to the positions of the multiple integrated circuit devices 10. Accordingly, the address generation section 14 may generate an address corresponding to the position of the integrated circuit device 10 based on the magnetic field measured by the magnetic measurement section 12.

The interface processing section 16 outputs the address generated by the address generation section 14. The interface processing section 16 may output the address generated by the address generation section 14 to the control device 20. The interface processing section 16 may execute various communication processings with the control device 20.

A sensor function of the integrated circuit device 10 in the sensor network system 100 may be a magnetic sensor function or may be another sensor function. For example, in the case where the sensor function of the integrated circuit device 10 in the sensor network system 100 is the magnetic sensor function, the magnetic measurement section 12 may serve to measure a magnetic field for being used by the address generation section 14, and may also serve to measure a magnetic field, as a magnetic sensor in the sensor network system 100. On the other hand, in the case where the sensor function of the integrated circuit device 10 in the sensor network system 100 is another sensor function different from the magnetic sensor function, the integrated circuit device 10 may include, in addition to the magnetic measurement section 12, another measurement section (for example, a temperature measurement section or optical measurement section) corresponding to that sensor function. In this case, by adding the magnetic measurement section 12 to an existing integrated circuit device that functions as an arbitrary sensor, the integrated circuit device 10 may be configured as an integrated circuit device in which an address is generated based on a magnetic field.

The control device 20 is communicably connected to the multiple integrated circuit devices 10. The control device 20 of the present example is communicably connected to the multiple integrated circuit devices 10 via a serial interface. The serial interface may be an inter-integrated circuit (I2C), an improved inter-integrated circuit (I3C), or a serial peripheral interface (SPI). However, the type of the serial interface is not limited thereto.

In the serial interface, each of the control device 20 and the multiple integrated circuit devices 10 includes an SCL terminal for clock signals and an SDA terminal for data signals. A data signal is communicated between the SDA terminals on the basis of a clock signal generated by the control device 20 and transmitted between the SCL terminals. The multiple integrated circuit devices 10 connected via the serial interface are distinguished by addresses, in which data transmission and reception are performed individually. However, in the case where the multiple integrated circuit devices 10 are the same product as each other and have the same unique address as each other, individual transmission and reception using the unique address sometimes cannot be realized.

In the sensor network system 100, mapping of sensor data is sometimes important. That is, it is sometimes important to acquire sensor data from each of the integrated circuit devices 10 and to identify which position the sensor data corresponds to.

In the sensor network system 100 of the present example, an address of each of the multiple integrated circuit devices 10 is generated based on the magnetic field measured by the magnetic measurement section 12. Accordingly, since the address of the integrated circuit device 10 can be associated with the position thereof, the sensor data and the position can also be correlated. Accordingly, in the sensor network system 100 of the present example, by a simple configuration in which the integrated circuit device 10 includes the magnetic measurement section 12, sensor data can be accurately mapped, and the sensor network system 100 that is compact and low-cost can be realized.

In the above description, the address generation section 14 of the integrated circuit device 10 has been described as generating addresses, but the subject that generates addresses is not limited thereto. For example, the control device 20 may receive information relating to a magnetic field from the integrated circuit device 10 and assign an address to the integrated circuit device 10 based on the magnetic field.

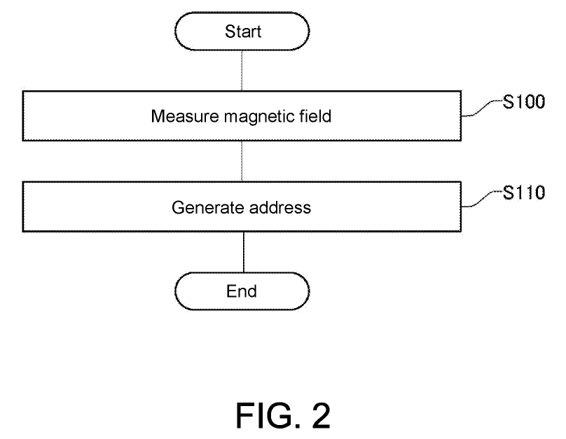

FIG. 2 shows an example of an address assignment method.

In step S100, the magnetic measurement section 12 of each of the multiple integrated circuit devices 10 measures a magnetic field. The magnetic field measured by the magnetic measurement section 12 may be a magnetic field having a position-dependent distribution. Details of the magnetic field measured by the magnetic measurement section 12 will be described later.

In step S110, an address of each of the multiple integrated circuit devices 10 is generated based on the magnetic field measured by the magnetic measurement section 12. The address of each of the multiple integrated circuit devices 10 may be generated by the address generation section 14 or may be generated by the control device 20. For example, the address generation section 14 generates an address based on the magnetic field measured by the magnetic measurement section 12 in accordance with a predetermined magnetic field-address conversion algorithm.

In the address assignment method of the present example, since the address of each of the multiple integrated circuit devices 10 is generated based on the magnetic field measured by the magnetic measurement section 12, the address of the integrated circuit device 10 can be associated with the position thereof. Accordingly, the sensor network system 100 that is compact and low-cost, in which sensor data can be accurately mapped, can be realized.

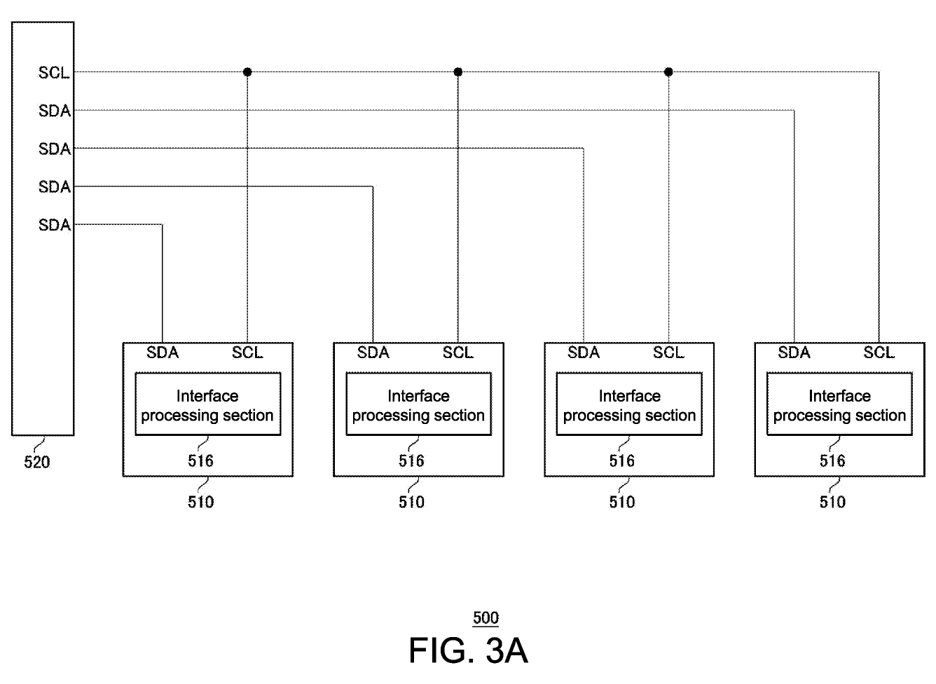

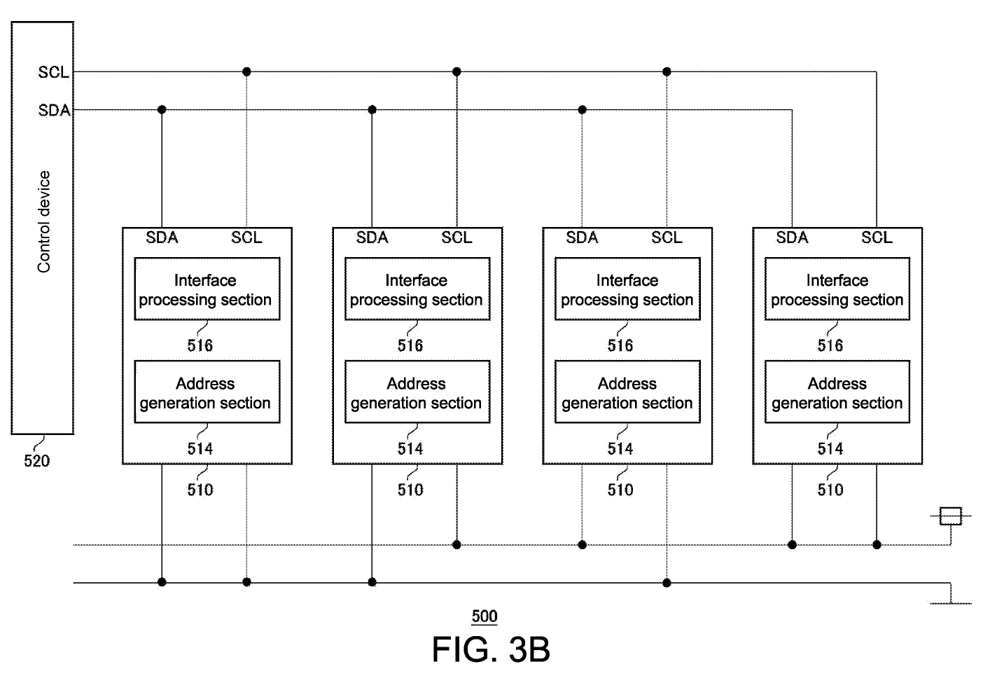

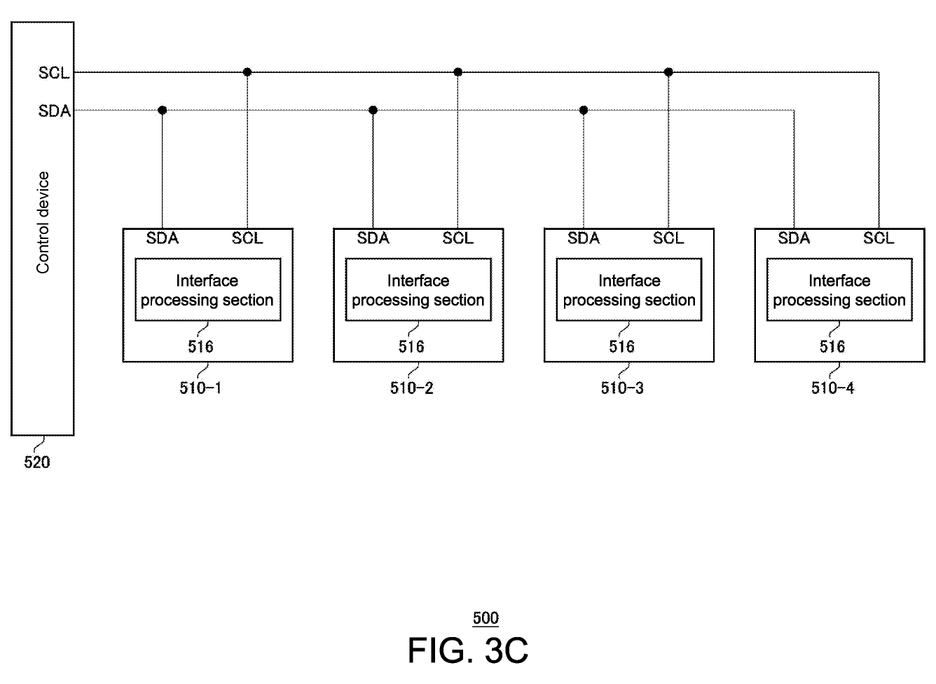

FIG. 3A shows an example of a sensor network system 500 according to a comparative example. Multiple integrated circuit devices 510 include no address generation section. In the sensor network system 500, in order to prevent confusion due to the same unique address and to distinguish each of the integrated circuit devices 510, SDA wiring is provided for each integrated circuit device 510. Accordingly, in the sensor network system 500, the number of wirings increases according to the number of integrated circuit devices 510, which sometimes leads to an increase in size of the sensor network system 500.

FIG. 3B shows an example of the sensor network system 500 according to a comparative example. The multiple integrated circuit devices 510 include no magnetic field measurement section. An address generation section 514 generates an address based on input from a separately provided address pin. Since the sensor network system 500 includes four integrated circuit devices 510, two address pins are provided for each of the integrated circuit devices 510 in order to distinguish the integrated circuit devices 510. However, as the number of integrated circuit devices 510 increases, the number of address pins that need to be separately provided increases. Accordingly, in the sensor network system 500, the integrated circuit device 510 is increased in size due to an increase in the number of pins according to the number of integrated circuit devices 510, which sometimes leads to an increase in size and cost of the sensor network system 500.

FIG. 3C shows an example of the sensor network system 500 according to a comparative example. Multiple integrated circuit devices 510-1 to 510-4 include no address generation section. The integrated circuit device 510-1, the integrated circuit device 510-2, the integrated circuit device 510-3, and the integrated circuit device 510-4 are different products from each other and have unique addresses different from each other. In the sensor network system 500, in order to distinguish the multiple integrated circuit devices 510-1 to 510-4, different types of products corresponding to the number of the multiple integrated circuit devices 510-1 to 510-4 are required. Accordingly, production management and implementation of the sensor network system 500 sometimes become difficult.

On the other hand, in the sensor network system 100 described in relation to FIG. 1 and FIG. 2, an address of each of the multiple integrated circuit devices 10 is generated based on the magnetic field measured by the magnetic measurement section 12. Accordingly, since the address of the integrated circuit device 10 can be associated with the position thereof, the sensor data and the position can also be correlated. Accordingly, in the sensor network system 100 of the present example, by a simple configuration in which the integrated circuit device 10 includes the magnetic measurement section 12, sensor data can be accurately mapped, and the sensor network system 100 that is compact and low-cost can be realized.

In FIG. 1 and FIG. 2, the multiple integrated circuit devices 10 have been described as being the same product as each other and having the same unique address to each other. However, in the sensor network system 100, the multiple integrated circuit devices 10 may also be different products having unique addresses different from each other. Even in this case, since the address of the integrated circuit device 10 can be associated with the position thereof based on the magnetic field measured by the magnetic measurement section 12, the sensor data and the position can also be correlated. There is an advantage that by a simple configuration in which the integrated circuit device 10 includes the magnetic measurement section 12, sensor data can be accurately mapped.

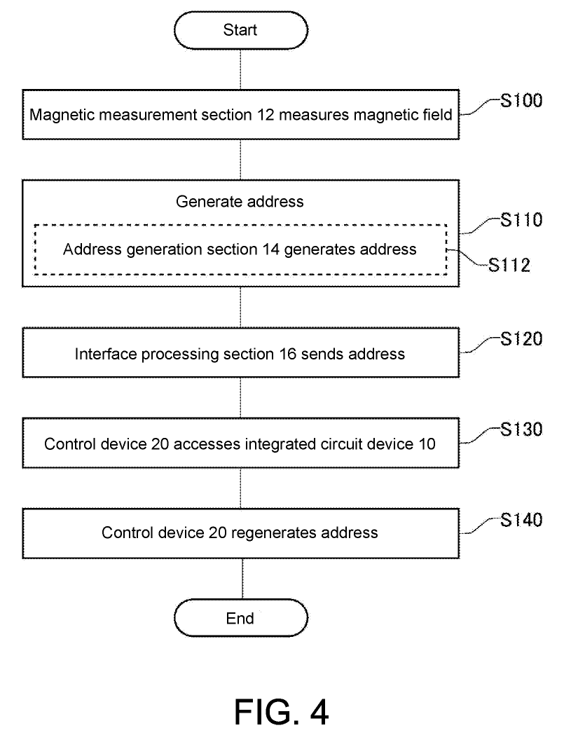

FIG. 4 shows a modification of an address assignment method.

In step S100, the magnetic measurement section 12 of each of multiple integrated circuit devices 10 measures a magnetic field. The magnetic field measured by the magnetic measurement section 12 may be a magnetic field having a position-dependent distribution. Details of step S100 in which the magnetic measurement section 12 measures the magnetic field will be described later.

In step S110, an address of each of the multiple integrated circuit devices 10 is generated based on the magnetic field measured by the magnetic measurement section 12. Step S110 in which an address is generated may include step S112 in which the address generation section 14 of each of the multiple integrated circuit devices 10 generates an address based on the magnetic field measured by the magnetic measurement section 12.

Step S110 in which an address is generated may include a step in which an address of each of the multiple integrated circuit devices 10 is generated based on at least one of magnitude and direction of the magnetic field measured by the magnetic measurement section 12. For example, the address generation section 14 of each of the multiple integrated circuit devices 10 generates an address based on at least one of magnitude and direction of the magnetic field measured by the magnetic measurement section 12. The address generation section 14 may generate an address based on at least one of magnitude and direction of the magnetic field measured by the magnetic measurement section 12 in accordance with a predetermined magnetic field-address conversion algorithm.

Step S110 in which an address is generated may include a step in which an address corresponding to a position of each of the multiple integrated circuit devices 10 is generated based on the magnetic field measured by the magnetic measurement section 12. For example, the magnetic field measured by the magnetic measurement section 12 is a magnetic field in which at least one of magnitude and direction differs according to the positions of the multiple integrated circuit devices 10. Accordingly, the address generation section 14 may generate an address corresponding to the position of the integrated circuit device 10 based on the magnetic field measured by the magnetic measurement section 12.

The multiple integrated circuit devices 10 may each include the magnetic measurement section 12 that uses a magnetic measurement sensor having a common specification, and may have a common magnetic field-address conversion algorithm that generates an address based on the magnetic field measured by the magnetic measurement section 12. Even in this case, by generating an address based on the magnetic field measured by the magnetic measurement section 12, the multiple integrated circuit devices 10 can be distinguished, and their addresses and positions can be associated.

In step S120, the interface processing section 16 of each of the multiple integrated circuit devices 10 transmits the address generated by the address generation section 14 to the control device 20 communicably connected to the multiple integrated circuit devices 10. For example, the interface processing section 16 of each of the multiple integrated circuit devices 10 may collectively output the address generated by the address generation section 14 using an arbitration function provided in a serial interface.

In step S130, the control device 20 accesses each of the multiple integrated circuit devices 10 using the address received from the interface processing section 16 as a provisional address. In step S140, the control device 20 regenerates at least one address of the multiple integrated circuit devices 10. The control device 20 may regenerate at least one address of the multiple integrated circuit devices 10 so that convenience of control of the multiple integrated circuit devices 10 in the sensor network system 100 is enhanced. For example, in the case where the addresses of the multiple integrated circuit devices 10 are not consecutive addresses, the control device 20 regenerates at least one address of the multiple integrated circuit devices 10 so that the addresses of the multiple integrated circuit devices 10 become consecutive addresses.

In the case where the control device 20 detects that two or more provisional addresses match among multiple provisional addresses received from each of the interface processing sections 16, the control device 20 may notify a warning via a user interface (not shown). The case where two or more provisional addresses match will be described later.

As described above, the address of each of the multiple integrated circuit devices 10 is generated based on the magnetic field measured by the magnetic measurement section 12. The address of each of the multiple integrated circuit devices 10 may be generated by the address generation section 14 or may be generated by the control device 20. The address of each of the multiple integrated circuit devices 10 may, after being generated by the address generation section 14, be regenerated by the control device 20 via communication using the address as a provisional address.

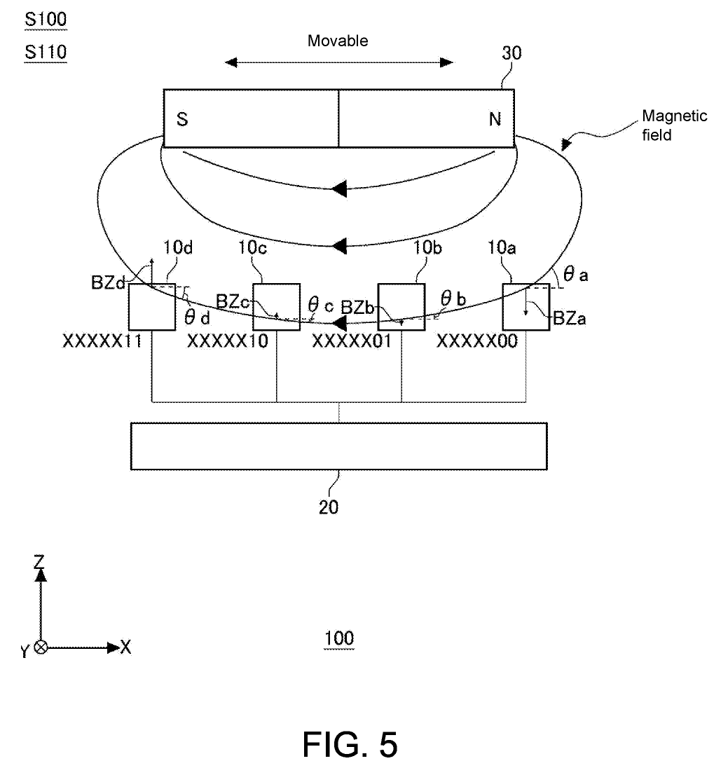

FIG. 5 shows an example of the sensor network system 100. The sensor network system 100 of the present example includes a magnetic field generation section 30. FIG. 5 shows an example of step S100 in which the magnetic measurement section 12 measures a magnetic field and step S110 in which an address of each of multiple integrated circuit devices 10 (shown as 10a, 10b, 10c, and 10d in FIG. 5) is generated based on the magnetic field.

The magnetic field generation section 30 may have a variable position relative to the multiple integrated circuit devices 10. For example, in the case where the sensor network system 100 is a sensor network system that detects a position and/or speed of a piston in a cylinder having the piston built therein and is included in a displacement detection device for the piston, the magnetic field generation section 30 may be a magnet built in the piston. However, the magnetic field generation section 30 is not limited thereto. The sensor network system 100 may include any magnetic field generation section 30 that generates a magnetic field for being used for address generation.

Step S100 in which a magnetic field is measured may include a step in which the magnetic measurement section 12 measures a magnetic field generated by the magnetic field generation section 30. The magnetic field generation section 30 may generate a magnetic field having a position-dependent distribution. For example, the magnetic field generated by the magnetic field generation section 30 is a magnetic field in which at least one of magnitude and direction differs according to the positions of the multiple integrated circuit devices 10. The magnetic field generation section 30 may be disposed at a predetermined reference position in order to generate a magnetic field having a position-dependent distribution. Step S100 in which a magnetic field is measured may include a step in which the magnetic measurement section 12 measures a magnetic field generated by the magnetic field generation section 30 disposed at the reference position.

Step S110 in which an address is generated may include a step in which an address of each of the multiple integrated circuit devices 10 is generated based on at least one of magnitude and direction of the magnetic field measured by the magnetic measurement section 12. For example, the address generation section 14 of each of the multiple integrated circuit devices 10 generates an address based on at least one of magnitude and direction of the magnetic field measured by the magnetic measurement section 12.

For example, the address generation section 14 generates an address based on a direction of a magnetic field in an XZ plane. In the case where the direction of the magnetic field is included in a predetermined angle range, the address generation section 14 may generate an address corresponding to the angle range. The angle range may be predetermined based on the reference position where the magnetic field generation section 30 is disposed.

In FIG. 5, for example, the magnetic field generation section 30 is disposed at a reference position where the multiple integrated circuit devices 10 and the magnetic field generation section 30 are arranged in line symmetry with respect to the Z-axis. Based on the reference position, angle ranges may be predetermined as (15 °, 90 °), (0 °, 15 °), (-15 °, 0 °), and (-90 °, -15 °). An angle range (θ1, θ2) represents a range of θ1 or more to θ2 or less.

In the integrated circuit device 10a, a direction θa of the magnetic field is included in the angle range (15 °, 90 °). Thus, the address generation section 14 of the integrated circuit device 10a generates an address XXXXX00 corresponding to the angle range (15 °, 90 °). In the integrated circuit device 10b, a direction θb of the magnetic field is included in the angle range (0 °, 15 °). Thus, the address generation section 14 of the integrated circuit device 10b generates an address XXXXX01 corresponding to the angle range (0 °, 15 °). In the integrated circuit device 10c, a direction θc of the magnetic field is included in the angle range (-15 °, 0 °). Thus, the address generation section 14 of the integrated circuit device 10c generates an address XXXXX10 corresponding to the angle range (-15 °, 0 °). In the integrated circuit device 10d, a direction θd of the magnetic field is included in the angle range (-90 °, -15 °). Thus, the address generation section 14 of the integrated circuit device 10d generates an address XXXXX11 corresponding to the angle range (-90 °, -15 °).

Since the magnetic field generated by the magnetic field generation section 30 has a position-dependent distribution, the predetermined angle range is also position-dependent. Accordingly, the address corresponding to the angle range is also position-dependent. Accordingly, the control device 20 is able to associate the address with the position of each of the multiple integrated circuit devices 10. For example, the control device 20 is able to identify that the integrated circuit device 10c having the address XXXXX10 is located at the third position from the right.

As described above, in the case where the control device 20 detects that two or more provisional addresses match among multiple provisional addresses received from each of the interface processing sections 16, the control device 20 may notify a warning via the user interface (not shown). For example, in the case where any of the multiple integrated circuit devices 10 is disposed at a position different from a predetermined position, that integrated circuit device 10 and another integrated circuit device 10 may measure the same magnetic field and generate the same address, or may measure different magnetic fields but generate the same address because the directions of the magnetic fields fall in the same angle range. In such a case, the control device 20 may notify a warning.

As another example, the address generation section 14 generates an address based on a value of a Z component of a magnetic field. In the case where a signed magnitude of the magnetic field is included in a predetermined value range, the address generation section 14 may generate an address corresponding to the value range. The value range may be predetermined based on the reference position where the magnetic field generation section 30 is disposed.

In FIG. 5, for example, the magnetic field generation section 30 is disposed at a reference position where the multiple integrated circuit devices 10 and the magnetic field generation section 30 are arranged in line symmetry with respect to the Z-axis. The value range may be predetermined as (-4mT, -2mT), (-2mT, 0mT), (0mT, 2mT), and (2mT, 4mT) based on the reference position. A value range (BZ1, BZ2) represents a range of BZ1 or more to BZ2 or less.

In the integrated circuit device 10a, a signed magnitude BZa of the magnetic field is included in the value range (-4mT, -2mT). Thus, the address generation section 14 of the integrated circuit device 10a generates the address XXXXX00 corresponding to the value range (-4mT, -2mT). In the integrated circuit device 10b, a signed magnitude BZb of the magnetic field is included in the value range (-2mT, 0mT). Thus, the address generation section 14 of the integrated circuit device 10b generates the address XXXXX01 corresponding to the value range (-2mT, 0mT). In the integrated circuit device 10c, a signed magnitude BZc of the magnetic field is included in the value range (0mT, 2mT). Thus, the address generation section 14 of the integrated circuit device 10c generates the address XXXXX10 corresponding to the value range (0mT, 2mT). In the integrated circuit device 10d, a signed magnitude BZd of the magnetic field is included in the value range (2mT, 4mT). Thus, the address generation section 14 of the integrated circuit device 10d generates the address XXXXX11 corresponding to the value range (2mT, 4mT).

Since the magnetic field generated by the magnetic field generation section 30 has a position-dependent distribution, the predetermined value range is also position-dependent. Accordingly, the address corresponding to the value range is also position-dependent. Accordingly, the control device 20 is able to associate the address with the position of each of the multiple integrated circuit devices 10. For example, the control device 20 is able to identify that the integrated circuit device 10c having the address XXXXX10 is located at the third position from the right.

As described above, in the case where the control device 20 detects that two or more provisional addresses match among multiple provisional addresses received from each of the interface processing sections 16, the control device 20 may notify a warning via the user interface (not shown). For example, in the case where any of the multiple integrated circuit devices 10 is disposed at a position different from the predetermined position, that integrated circuit device 10 and another integrated circuit device 10 may measure the same magnetic field and generate the same address, or may measure different magnetic fields but generate the same address because the signed magnitudes of the magnetic field fall win the same value range. In such a case, the control device 20 may notify a warning.

In the above, an example has been described in which the predetermined angle range and the predetermined value range are classified into four ranges. However, the number of angle ranges and value ranges is not limited thereto. The number of angle ranges and value ranges may be predetermined according to the number of the multiple integrated circuit devices 10. For example, if the number of the multiple integrated circuit devices 10 is 8, it is understood that the number of angle ranges and value ranges may also be 8. The number of angle ranges and value ranges does not need to match the number of the multiple integrated circuit devices 10, and may be equal to or more than the number of the multiple integrated circuit devices 10.

In the above, an example has been described in which an address is generated based on the direction of the magnetic field in the XZ plane or the value of the Z component of the magnetic field. However, a method for generating an address based on a magnetic field is not limited thereto. For example, if multiple integrated circuit devices 10 are also arranged in the Y-axis direction, it is understood that the magnetic field in the Y-axis direction may also be further considered. The address generation section 14 may generate an address based on a component, magnitude and/or direction of a magnetic field that enables the positions of the multiple integrated circuit devices 10 to be identified.

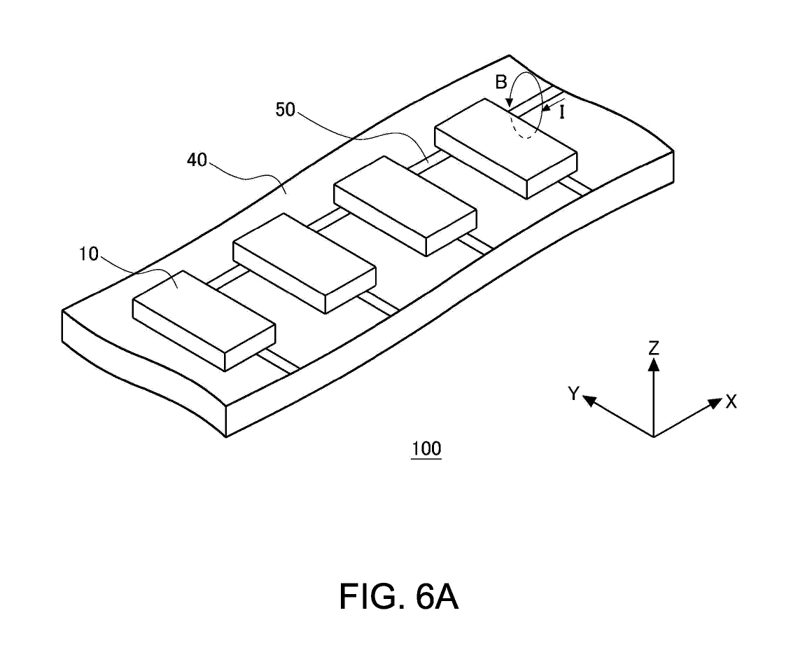

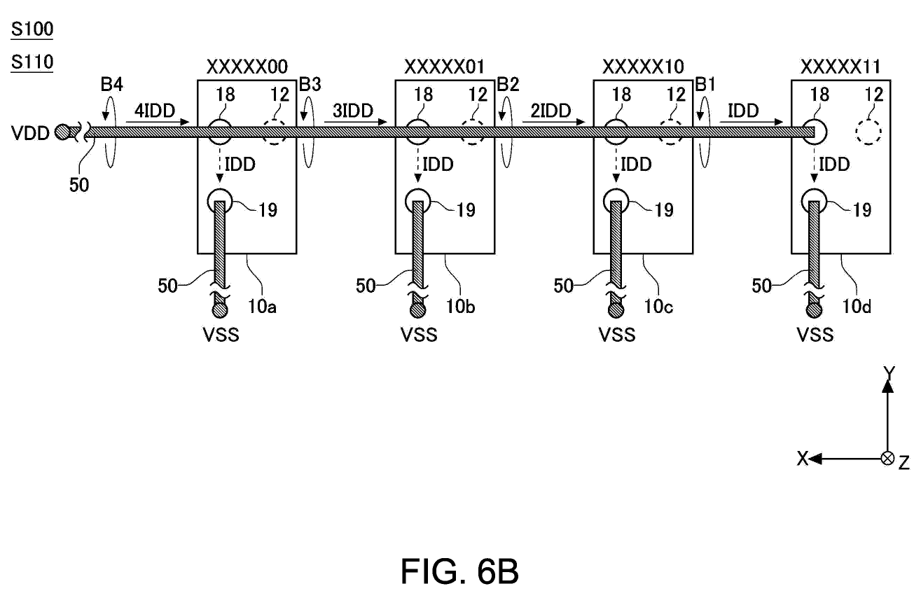

FIG. 6A shows a partial perspective view of a modification of the sensor network system 100. The sensor network system 100 of the present example includes a board 40 and a wiring part 50 provided on the board 40. Multiple integrated circuit devices 10 may be provided on the board 40. The multiple integrated circuit devices 10 may be electrically connected to each other via the wiring part 50. Step S100 in which a magnetic field is measured may include a step in which the magnetic measurement section 12 measures a magnetic field B generated by a current I flowing through the wiring part 50.

In the sensor network system 100 of the present example, even if an application for installing the multiple integrated circuit devices 10 does not allow installation of a magnet (magnetic field generation source) capable of forming a magnetic field that sufficiently covers an installation space or layout of the sensor network system 100, address generation is possible. Such a sensor network system 100 can also be applied to a monitoring system for a structure that diagnoses deterioration of a bridge pillar or estimates a degree of fatigue of a blade or tower for wind power generation, in combination with, for example, a pressure sensor, strain sensor, vibration sensor or acceleration sensor. Since the illustrated structure is provided in various sizes or shapes, the number of sensors to be arranged that detect a state of the structure is not uniquely determined. By applying the sensor network system 100 of the present example, a monitoring system can be constructed in a relatively flexible manner.

FIG. 6B shows a bottom view of a modification of the sensor network system 100. FIG. 6B is a view of the sensor network system 100 of FIG. 6A as seen from the -Z-axis direction. In FIG. 6B, the board 40 is omitted. FIG. 6B shows an example of step S100 in which the magnetic measurement section 12 measures a magnetic field and step S110 in which an address of each of multiple integrated circuit devices 10 is generated based on the magnetic field.

The multiple integrated circuit devices 10 may include a first terminal 18 and a second terminal 19. The first terminal 18 of each integrated circuit device 10 is connected to a VDD potential. The second terminal 19 of each integrated circuit device 10 is connected to a VSS potential. The wiring part 50 may connect the first terminal 18 of each of the multiple integrated circuit devices 10 in series. In FIG. 6B, only some members are shown, and other members are omitted. For example, the multiple integrated circuit devices 10 may include other terminals besides the first terminal 18 and the second terminal 19, and may include an SCL terminal and an SDA terminal for communicating with the control device 20.

The magnetic measurement section 12 may be provided inside the integrated circuit device 10. For example, the magnetic measurement section 12 is provided at a position overlapping the wiring part 50 inside the integrated circuit device 10. The magnetic measurement section 12 may be provided closer to the first terminal 18 than to the second terminal 19 inside the integrated circuit device 10. However, the position where the magnetic measurement section 12 is provided is not limited thereto. The magnetic measurement section 12 may be provided at a position where it is able to measure a magnetic field generated by a current flowing through the wiring part 50.

Step S100 in which a magnetic field is measured may include a step in which the magnetic measurement section 12 measures a magnetic field generated by a current flowing through the wiring part 50. As described above, the magnetic field measured by the magnetic measurement section 12 may be a magnetic field having a position-dependent distribution. In the present example, since the current flowing through the wiring part 50 has a position-dependent distribution, the magnetic field measured by the magnetic measurement section 12 also has a position-dependent distribution.

The step in which the magnetic measurement section 12 measures the magnetic field generated by the current flowing through the wiring part 50 may include a step in which each of the multiple integrated circuit devices 10 draws the current flowing through the wiring part 50 from the first terminal 18 into the inside. Each of the integrated circuit devices 10 in the present example is configured such that an internal circuit connecting the first terminal 18 and the second terminal 19 draws a current having a magnitude of IDD from the wiring part 50.

In the sensor network system 100 of the present example, a current having a magnitude of 4IDD flows through the wiring part 50 before the first terminal 18 of the integrated circuit device 10a. A current having a magnitude of IDD is drawn into the integrated circuit device 10a from the first terminal 18 of the integrated circuit device 10a, and a current having a magnitude of 3IDD flows through the wiring part 50 after the first terminal 18 of the integrated circuit device 10a and before the first terminal 18 of the integrated circuit device 10b. A current having a magnitude of IDD is drawn into the integrated circuit device 10b from the first terminal 18 of the integrated circuit device 10b, and a current having a magnitude of 2IDD flows through the wiring part 50 after the first terminal 18 of the integrated circuit device 10b and before the first terminal 18 of the integrated circuit device 10c. A current having a magnitude of IDD is drawn into the integrated circuit device 10c from the first terminal 18 of the integrated circuit device 10c, and a current having a magnitude of IDD flows through the wiring part 50 after the first terminal 18 of the integrated circuit device 10c and before the first terminal 18 of the integrated circuit device 10d.

Step S110 in which an address is generated may include a step in which an address of each of the multiple integrated circuit devices 10 is generated based on at least one of magnitude and direction of the magnetic field measured by the magnetic measurement section 12. For example, the address generation section 14 of each of the multiple integrated circuit devices 10 generates an address based on at least one of magnitude and direction of the magnetic field measured by the magnetic measurement section 12.

The address generation section 14 of the present example generates an address based on the magnitude of the magnetic field. In the case where the magnitude of the magnetic field is included in a predetermined value range, the address generation section 14 may generate an address corresponding to the value range. The value range may be predetermined based on a magnitude of a current supplied to the wiring part 50 and a magnitude of a current drawn by each integrated circuit device 10.

In FIG. 6B, as described above, a current having a magnitude of 4IDD is supplied to the wiring part 50, and each integrated circuit device 10 draws a current having a magnitude of IDD. The value range may be predetermined as (2.5 mT, 3.5 mT), (1.5 mT, 2.5 mT), (0.5 mT, 1.5 mT), and (0 mT, 0.5 mT) based on the magnitude of the current.

In the magnetic measurement section 12 of the integrated circuit device 10a, a magnitude B3 of a magnetic field corresponding to the current 3IDD is included in the value range (2.5 mT, 3.5 mT). Thus, the address generation section 14 of the integrated circuit device 10a generates an address XXXXX00 corresponding to the value range (2.5 mT, 3.5 mT). In the magnetic measurement section 12 of the integrated circuit device 10b, a magnitude B2 of a magnetic field corresponding to the current 2IDD is included in the value range (1.5 mT, 2.5 mT). Thus, the address generation section 14 of the integrated circuit device 10b generates an address XXXXX01 corresponding to the value range (1.5 mT, 2.5 mT). In the magnetic measurement section 12 of the integrated circuit device 10c, a magnitude B1 of a magnetic field corresponding to the current IDD is included in the value range (0.5 mT, 1.5 mT). Thus, the address generation section 14 of the integrated circuit device 10c generates an address XXXXX10 corresponding to the value range (0.5 mT, 1.5 mT). In the integrated circuit device 10d, since there is no current generating a magnetic field, the magnitude of the magnetic field is included in the value range (0 mT, 0.5 mT). Thus, the address generation section 14 of the integrated circuit device 10d generates an address XXXXX11 corresponding to the value range (0 mT, 0.5 mT).

Since the magnetic field measured by the magnetic measurement section 12 has a position-dependent distribution, the predetermined value range is also position-dependent. Accordingly, the address corresponding to the value range is also position-dependent. Accordingly, the control device 20 is able to associate the address with the position of each of the multiple integrated circuit devices 10. For example, the control device 20 is able to identify that the integrated circuit device 10c having the address XXXXX10 is located at the third position from an upstream side of the wiring part 50.

As described above, in the case where the control device 20 detects that two or more provisional addresses match among multiple provisional addresses received from each of the interface processing sections 16, the control device 20 may notify a warning via the user interface (not shown). For example, in the case where any of the multiple integrated circuit devices 10 is connected in parallel rather than in series, that integrated circuit device 10 and another integrated circuit device 10 may measure the same magnetic field and generate the same address. In such a case, the control device 20 may notify a warning.

In the above, an example has been described in which the predetermined value range is classified into four ranges. However, the number of value ranges is not limited thereto. The number of value ranges may be predetermined according to the number of the multiple integrated circuit devices 10. For example, if the number of the multiple integrated circuit devices 10 is 8, it is understood that the number of value ranges may also be 8. The number of value ranges does not need to match the number of the multiple integrated circuit devices 10, and may be equal to or more than the number of the multiple integrated circuit devices 10.

In the above, an example has been described in which the magnitude of the current drawn by each integrated circuit device 10 is equal. However, the current drawn by each integrated circuit device 10 may differ in magnitude. In this case, the value ranges do not need to be at equal intervals, and may have different intervals according to the magnitude of the current drawn by each integrated circuit device 10.

Various embodiments of the disclosure may be described with reference to flowcharts and block diagrams, in which blocks may represent (1) stages of a process in which operations are performed or (2) sections of a device responsible for performing operations. Specific stages and sections may be implemented by dedicated circuits, programmable circuits supplied together with computer-readable instructions stored on a computer-readable medium, and/or processors supplied together with computer-readable instructions stored on a computer-readable medium. The dedicated circuits may include digital and/or analog hardware circuits, and may include integrated circuits (ICs) and/or discrete circuits. The programmable circuits may include reconfigurable hardware circuits including logic AND, logic OR, logic XOR, logic NAND, logic NOR, and other logic operations, memory elements such as flip-flops, registers, field programmable gate arrays (FPGAs), and programmable logic arrays (PLAs), and the like.

The computer-readable medium may include any tangible device capable of storing instructions to be executed by an appropriate device, such that a computer-readable medium having instructions stored thereon includes an article of manufacture including instructions that can be executed to create means for performing operations specified in flowcharts or block diagrams. Examples of the computer-readable medium may include an electronic storage medium, a magnetic storage medium, an optical storage medium, an electromagnetic storage medium, and a semiconductor storage medium. More specific examples of the computer-readable medium may include a floppy (registered trademark) disk, a diskette, a hard disk, a random access memory (RAM), a read-only memory (ROM), an erasable programmable read-only memory (EPROM or flash memory), an electrically erasable programmable read-only memory (EEPROM), a static random access memory (SRAM), a compact disc read-only memory (CD-ROM), a digital versatile disc (DVD), a Blu-ray (RTM) disc, a memory stick, and an integrated circuit card.

The computer-readable instructions may include assembler instructions, instruction set architecture (ISA) instructions, machine instructions, machine-dependent instructions, microcode, firmware instructions, state setting data, or either source code or object code written in any combination of one or more programming languages, including object-oriented programming languages such as Smalltalk (registered trademark), JAVA (registered trademark), and C++, and conventional procedural programming languages such as the “C” programming language or similar programming languages.

The computer-readable instructions may be provided to a processor or programmable circuit of a programmable data processing device such as a computer, either locally or via a wide area network (WAN) such as a local area network (LAN) and the Internet, and the computer-readable instructions may be executed to create means for performing operations specified in flowcharts or block diagrams. Here, the computer may be a personal computer (PC), a tablet computer, a smartphone, a workstation, a server computer, a general-purpose computer, a special-purpose computer, or the like, and may be a computer system in which multiple computers are connected. Such a computer system in which multiple computers are connected is also referred to as a distributed computing system, which is a computer in a broad sense. In a distributed computing system, each of the multiple computers executes a portion of a program, and the multiple computers collectively execute the program by passing data during program execution between computers as needed.

Examples of the processor include a computer processor, a central processing unit (CPU), a processing unit, a microprocessor, a digital signal processor, a controller, and a microcontroller. The computer may include one processor or multiple processors. In a multiprocessor system including multiple processors, each processor executes a portion of a program, and the multiple processors collectively execute the program by passing data during program execution between processors as needed. For example, in execution of multitasking, each of the multiple processors may execute a portion of each task in small pieces by performing task switching at each time slice. In this case, which portion of one program each processor executes changes dynamically. Which portion of a program each of the multiple processors executes may be determined statically by multiprocessor-aware programming.

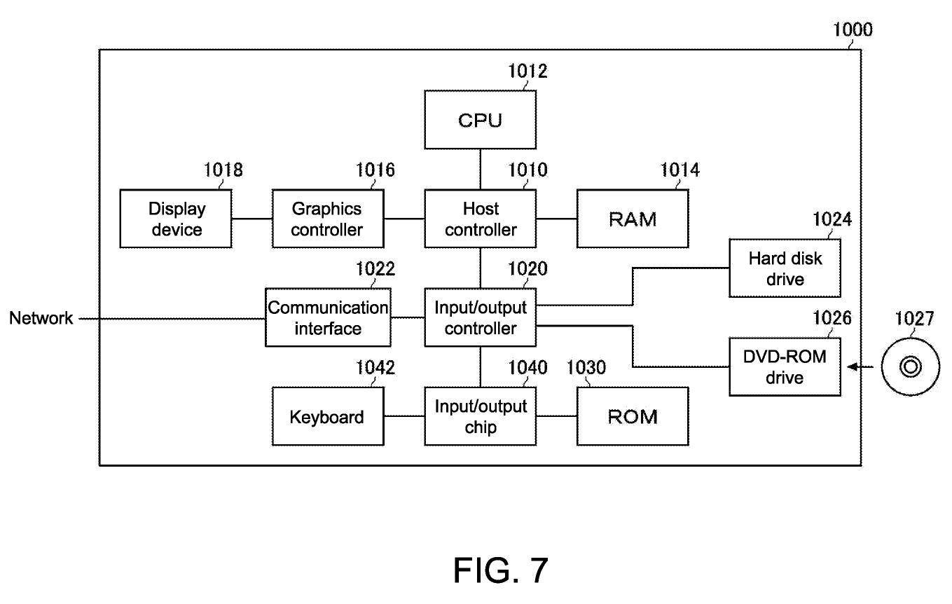

FIG. 7 shows an example of a computer 1000 in which multiple aspects of the disclosure may be embodied in whole or in part. A program installed in the computer 1000 can cause the computer 1000 to function as an operation associated with a device according to an embodiment of the disclosure or as one or more sections of the device, or can cause the computer 1000 to execute the operation or the one or more sections, and/or can cause the computer 1000 to execute a process according to an embodiment of the disclosure or a stage of the process. Such a program may be executed by a CPU 1012 to cause the computer 1000 to perform a specific operation associated with some or all of the blocks in the flowcharts and block diagrams described herein.

The computer 1000 according to the present embodiment includes the CPU 1012, a RAM 1014, a graphic controller 1016, and a display device 1018, which are connected to each other by a host controller 1010. The computer 1000 also includes input/output units such as a communication interface 1022, a hard disk drive 1024, a DVD-ROM drive 1026, and an IC card drive, which are connected to the host controller 1010 via an input/output controller 1020. The computer also includes legacy input/output units such as a ROM 1030 and a keyboard 1042, which are connected to the input/output controller 1020 via an input/output chip 1040.

The CPU 1012 operates according to a program stored in the ROM 1030 and the RAM 1014, thereby controlling each unit. The graphic controller 1016 acquires image data generated by the CPU 1012 in a frame buffer or the like provided in the RAM 1014 or in itself, and causes the image data to be displayed on the display device 1018.

The communication interface 1022 communicates with other electronic devices via a network. The hard disk drive 1024 stores programs and data used by the CPU 1012 in the computer 1000. The DVD-ROM drive 1026 reads programs or data from a DVD-ROM 1027 and provides the programs or data to the hard disk drive 1024 via the RAM 1014. The IC card drive reads programs and data from an IC card and/or writes programs and data to an IC card.

The ROM 1030 stores therein a boot program or the like executed by the computer 1000 upon activation, and/or programs dependent on the hardware of the computer 1000. The input/output chip 1040 may also connect various input/output units to the input/output controller 1020 via a parallel port, a serial port, a keyboard port, a mouse port, or the like.

A program is provided by a computer-readable medium such as the DVD-ROM 1027 or an IC card. The program is read from the computer-readable medium, installed in the hard disk drive 1024, the RAM 1014, or the ROM 1030, which are also examples of the computer-readable medium, and executed by the CPU 1012. The information processing described in these programs is read by the computer 1000 and brings about cooperation between the programs and the various types of hardware resources described above. A device or method may be configured by realizing manipulation or processing of information according to the use of the computer 1000.

For example, in the case where communication is executed between the computer 1000 and an external device, the CPU 1012 may execute a communication program loaded in the RAM 1014 and may instruct the communication interface 1022 to perform communication processing based on the processing described in the communication program. Under the control of the CPU 1012, the communication interface 1022 reads transmission data stored in a transmission buffer processing area provided in a recording medium such as the RAM 1014, the hard disk drive 1024, the DVD-ROM 1027, or an IC card, and transmits the read transmission data to a network, or writes reception data received from the network to a reception buffer processing area or the like provided on the recording medium.

The CPU 1012 may also cause the whole or a required portion of a file or database stored in an external recording medium such as the hard disk drive 1024, the DVD-ROM drive 1026 (DVD-ROM 1027), an IC card, or the like to be read into the RAM 1014, and execute various types of processing on data on the RAM 1014. The CPU 1012 then writes back the processed data to the external recording medium.

Various types of information such as various types of programs, data, tables, and databases may be stored in a recording medium and subjected to information processing. The CPU 1012 may execute, on the data read from the RAM 1014, various types of processing including various types of operations, information processing, conditional determination, conditional branch, unconditional branch, search/replacement of information, and the like, which are described throughout the disclosure and specified by an instruction sequence of a program, and writes back a result to the RAM 1014. The CPU 1012 may also search for information in a file, a database, or the like in the recording medium. For example, in the case where multiple entries each having an attribute value of a first attribute associated with an attribute value of a second attribute are stored in the recording medium, the CPU 1012 may search for an entry matching a condition in which an attribute value of the first attribute is specified from among the multiple entries, read an attribute value of the second attribute stored in the entry, and thereby acquire an attribute value of the second attribute associated with the first attribute satisfying a predetermined condition.

The program or software module described above may be stored in a computer-readable medium on or in the vicinity of the computer 1000. A recording medium such as a hard disk or a RAM provided in a server system connected to a dedicated communication network or the Internet may also be used as the computer-readable medium, thereby providing the program to the computer 1000 via a network.

Although the description has been made above using the embodiments, the technical scope of the disclosure is not limited to the scope described in the above embodiments. It is apparent to those skilled in the art that various modifications or improvements can be added to the above embodiments. It is apparent from the description of the claims that forms with such modifications or improvements added may also be included in the technical scope of the disclosure.

It should be noted that the execution order of each processing such as operations, procedures, steps, and stages in the device, system, program, and method shown in the claims, the specification, and the drawings may be realized in any order unless specifically indicated as “before” or “prior to” and unless an output of a previous processing is used in a subsequent processing. Even if the operation flow in the claims, the specification, and the drawings is described using “first,” “next,” and the like for convenience, this does not mean that implementation in this order is mandatory.

What is claimed is:

1. An address assignment method comprising:
a stage in which a magnetic measurement section of each of a plurality of integrated circuit devices measures a magnetic field; and
a stage in which an address of each of the plurality of integrated circuit devices is generated based on the magnetic field.

2. The address assignment method according to claim 1, wherein
the stage in which the address is generated comprises a stage in which an address generation section of each of the plurality of integrated circuit devices generates the address based on the magnetic field.

3. The address assignment method according to claim 2, comprising:
a stage in which an interface processing section of each of the plurality of integrated circuit devices transmits the address generated by the address generation section to a control device communicably connected to the plurality of integrated circuit devices.

4. The address assignment method according to claim 3, comprising:
a stage in which the control device accesses each of the plurality of integrated circuit devices using the address received from the interface processing section as a provisional address; and
a stage in which the control device regenerates the address of at least one of the plurality of integrated circuit devices.

5. The address assignment method according to claim 1, wherein
the stage in which the address is generated comprises a stage in which the address corresponding to a position of each of the plurality of integrated circuit devices is generated based on the magnetic field.

6. The address assignment method according to claim 1, wherein
the stage in which the address is generated comprises a stage in which an address of each of the plurality of integrated circuit devices is generated based on at least one of magnitude and direction of the magnetic field.

7. The address assignment method according to claim 1, wherein
the stage in which the magnetic field is measured comprises a stage in which the magnetic measurement section measures a magnetic field generated by a magnetic field generation section whose position relative to the plurality of integrated circuit devices is variable.

8. The address assignment method according to claim 1, wherein
the stage in which the magnetic field is measured comprises a stage in which the magnetic measurement section measures a magnetic field generated by a current flowing through a wiring part that connects a first terminal of each of the plurality of integrated circuit devices in series.

9. The address assignment method according to claim 8, wherein
the stage in which the magnetic measurement section measures the magnetic field generated by the current flowing through the wiring part comprises a stage in which each of the plurality of integrated circuit devices draws the current flowing through the wiring part from the first terminal into inside.

10. A sensor network system comprising:
a plurality of integrated circuit devices, each comprising a magnetic measurement section that measures a magnetic field; and
a control device, communicably connected to the plurality of integrated circuit devices, wherein
an address of each of the plurality of integrated circuit devices is generated based on the magnetic field measured by the magnetic measurement section.

11. The sensor network system according to claim 10, wherein
the control device is communicably connected to the plurality of integrated circuit devices via a serial interface.

12. A displacement detection device, comprising the sensor network system according to claim 10.

13. A non-transitory computer-readable medium storing a program that, when executed by a computer, causes the computer to:
control a magnetic measurement section of each of a plurality of integrated circuit devices to measure a magnetic field; and
generate an address of each of the plurality of integrated circuit devices based on the magnetic field.

14. An integrated circuit device comprising:
a magnetic measurement section, measuring a magnetic field;
an address generation section, generating an address based on the magnetic field; and
an interface processing section, outputting the address.
